(19) United States
(12) Patent Application Publication
(10) Pub. No.: US 2006/0273345 A1
(43) Pub. Date: Dec. 7, 2006

(54) Method of manufacturing liquid crystal display, liquid crystal display, and aging system

(75) Inventors: Woo-geun Lee, Yongin-si (KR); Jae-hong Jeon, Yongin-si (KR); Shi-yul Kim, Yongin-si (KR); Jang-soo Kim, Suwon-si (KR); Hye-young Ryu, Seoul (KR)

Correspondence Address: F. CHAU & ASSOCIATES, LLC, 130 WOODBURY ROAD, WOODBURY, NY, 11797, US

(73) Assignee: Samsung Electronics Co., LTD., Suwon-si (KR)

(21) Appl. No.: 11/403,120

(22) Filed: Apr. 12, 2006

(30) Foreign Application Priority Data
Jun. 1, 2005 (KR) 10-2005-0046883

(51) Int. Cl. H01L 29/74

(52) U.S. Cl. 257/147

(57) ABSTRACT

Provided are a method of manufacturing a liquid crystal display including an amorphous silicon thin film transistor, a liquid crystal display, and an aging system adapted to the method of manufacturing the liquid crystal display. The method includes providing a liquid crystal display including a liquid crystal panel having a plurality of thin film transistors, each thin film transistor comprising a gate electrode, a semiconductor layer formed on the gate electrode, and a drain electrode and a source electrode formed on the semiconductor layer and overlapping respective sides of the gate electrode, and wherein a first voltage is applied to the gate electrode, a second voltage is applied to the drain electrode, and the first voltage minus the second voltage is less than a third voltage minus a fourth voltage, in which the third voltage is a voltage applied to the gate electrode to deactivate the plurality of thin film transistors upon normal operation of the liquid crystal panel, and the fourth voltage is a maximal voltage applied to the drain electrode upon normal operation of the liquid crystal panel.

### CROSS-REFERENCE TO RELATED PATENT APPLICATION

This application claims priority from Korean Patent Application No. 10-2005-0046883, filed on Jun. 1, 2005, in the Korean Intellectual Property Office, the disclosure of which is incorporated by reference herein in its entirety.

### BACKGROUND OF THE INVENTION

1. Field of the Invention

The present invention relates to a method of manufacturing a liquid crystal display, a liquid crystal display, and an aging system. More particularly, the present invention relates to a method of manufacturing a liquid crystal display including an amorphous silicon thin film transistor, a liquid crystal display, and an aging system used in the method.

2. Description of the Related Art

A liquid crystal display (“LCD”) includes a color filter array substrate having a common electrode and an array of color filters, and a thin film transistor array substrate having a plurality of pixel electrodes and thin film transistors (“TFT”s). A liquid crystal layer is interposed between the color filter array substrate and the TFT array substrate. The orientations of molecules of the liquid crystal layer are changed by adjusting an electric field generated by the potential difference between the pixel electrodes and the common electrodes. The change of the orientations of the liquid crystal molecules causes the transmittance of light passing through the LCD to be varied, thereby obtaining desired images.

When a drain electrode, a source electrode and an amorphous silicon-based semiconductor layer of a TFT are formed using a single mask, a considerable portion of the semiconductor layer is exposed to light emitted from a backlight. The exposure of the amorphous silicon-based semiconductor layer to light induces light leakage current, thereby leading to a change in conductivity. In other words, when a portion of an amorphous silicon-based semiconductor layer adjacent to a gate electrode is exposed to light emitted from a backlight, leakage current may occur.

Furthermore, such a light leakage current causes a residual image on a liquid crystal display. During a residual image test, no residual image is left on residual image test patterns of TFTs driven with backlight shielding, whereas residual images are left on residual image test patterns of normally driven TFTs. The driving voltage of each TFT varies under normal operation of a backlight. This leads to a difference in light leakage current, varying effective voltages applied to a pixel electrode and a common electrode formed on a color filter, thereby creating a residual image.

### SUMMARY OF THE INVENTION

Embodiments of the present invention provide a liquid crystal display and method of manufacturing a liquid crystal display reducing a residual image that may be created due to a change in light leakage current, and an aging system used for the method of manufacturing the liquid crystal display.

According to an embodiment of the present invention, there is provided a method of manufacturing a liquid crystal display, the method including providing a liquid crystal display comprising a liquid crystal panel having a plurality of thin film transistors, each thin film transistor comprising a gate electrode, a semiconductor layer formed on the gate electrode, and a drain electrode and a source electrode formed on the semiconductor layer and overlapping respective sides of the gate electrode, and applying a first voltage to the gate electrode and a second voltage to the drain electrode, wherein the first voltage minus the second voltage is less than a third voltage minus a fourth voltage, in which the third voltage is a voltage applied to the gate electrode to deactivate the plurality of thin film transistors upon normal operation of the liquid crystal panel, and the fourth voltage is a maximal voltage applied to the drain electrode upon normal operation of the liquid crystal panel.

According to an embodiment of the present invention, there is provided a method of manufacturing a liquid crystal display, the method including providing a liquid crystal display including a liquid crystal panel, a driving voltage generating unit, a gate driving unit and a switching unit, the liquid crystal panel having a plurality of thin film transistors, each thin film transistor comprising a gate electrode, a semiconductor layer formed on the gate electrode, and a drain electrode and a source electrode formed on the semiconductor layer and overlapping respective sides of the gate electrode, the driving voltage generating unit supplying a gate-off voltage for deactivating the plurality of thin film transistors, the gate driving unit sequentially applying gate signals to gate lines of the liquid crystal panel, and the switching unit determining the transmission of the gate-off voltage from the driving voltage generating unit to the gate driving unit; and applying a first voltage to the gate electrode and a second voltage to the drain electrode, wherein the first voltage minus the second voltage is less than a third voltage minus a fourth voltage, in which the third voltage is a voltage applied to the gate electrode to deactivate the plurality of thin film transistors upon normal operation of the liquid crystal panel, and the fourth voltage is a maximal voltage applied to the drain electrode upon normal operation of the liquid crystal panel.

According to an embodiment of the present invention, there is provided a liquid crystal display including a liquid crystal panel having a plurality of thin film transistors, each thin film transistor comprising a gate electrode, a semiconductor layer disposed on the gate electrode, and a drain electrode and a source electrode, disposed on the semiconductor layer and overlapping respective sides of the gate electrode, a driving voltage generating unit supplying a gate-off voltage for deactivating the plurality of thin film transistors, a gate driving unit sequentially applying gate signals to gate lines of the liquid crystal panel, and a switching unit determining the transmission of the gate-off voltage from the driving voltage generating unit to the gate driving unit.

According to an embodiment of the present invention, there is provided an aging system including a direct current voltage supply unit applying a first voltage to a gate electrode of a thin film transistor and a second voltage to a drain electrode of the thin film transistor, wherein the first voltage minus the second voltage is less than a third voltage minus a fourth voltage, when the third voltage is a voltage applied to the gate electrode to deactivate the thin film transistor upon normal operation of a liquid crystal display, and the fourth voltage is a maximal voltage applied to the drain electrode upon normal operation of the liquid crystal display, and a high voltage stress (HVS) voltage supply unit supplying a voltage for stabilizing the gate driving unit and the data driving unit of the liquid crystal display to the gate driving unit and the gamma voltage generating unit, wherein the liquid crystal display includes a driving voltage generating unit supplying a gate-off voltage for deactivating the thin film transistor, a gate driving unit sequentially applying gate signals to gate lines of a liquid crystal panel, a data driving unit applying data signals to data lines of the liquid, crystal panel, and a gamma voltage generating unit generating a gamma voltage based on an array power voltage supplied from the driving voltage generating unit.

### BRIEF DESCRIPTION OF THE DRAWINGS

Exemplary embodiments of the present invention can be understood in more detail from the following description taken in conjunction with the attached drawings in which:

FIG. 1 is a circuit diagram illustrating a connection between a liquid crystal panel according to an embodiment of the present invention and a direct current voltage supply unit;

FIG. 2 is a sectional view of a thin film transistor of a liquid crystal display according to an embodiment of the present invention;

FIG. 3 illustrates applied voltage levels in a method of manufacturing a liquid crystal display according to an embodiment of the present invention;

FIG. 4 is a circuit diagram illustrating a connection between a liquid crystal display and an aging system according to an embodiment of the present invention;

FIG. 5 is a flow diagram illustrating a method of manufacturing a liquid crystal display according to another embodiment of the present invention;

FIG. 6 illustrates voltage levels to be applied from a direct current voltage supply unit in the method of manufacturing a liquid crystal display according to another embodiment of the present invention;

FIG. 7 graphically represents a change in the light leakage current when an application of a method of manufacturing a liquid crystal display according to an embodiment of the present invention is not made, when the application of the method is made and an application of white stress after the application of the method;

FIG. 8 graphically represents a residual image viewing factor with respect to a voltage applied to a gate electrode in a method of manufacturing a liquid crystal display according to an embodiment of the present invention; and

FIG. 9 graphically represents a residual image viewing factor with respect to a voltage application time in a method of manufacturing a liquid crystal display according to an embodiment of the present invention.

### DETAILED DESCRIPTION OF EXEMPLARY EMBODIMENTS

Exemplary embodiments of the present invention will now be described more fully with reference to the accompanying drawings. The present invention may, however, be embodied in many different forms and should not be construed as being limited to the embodiments set forth herein. Like reference numerals refer to like elements throughout the specification.

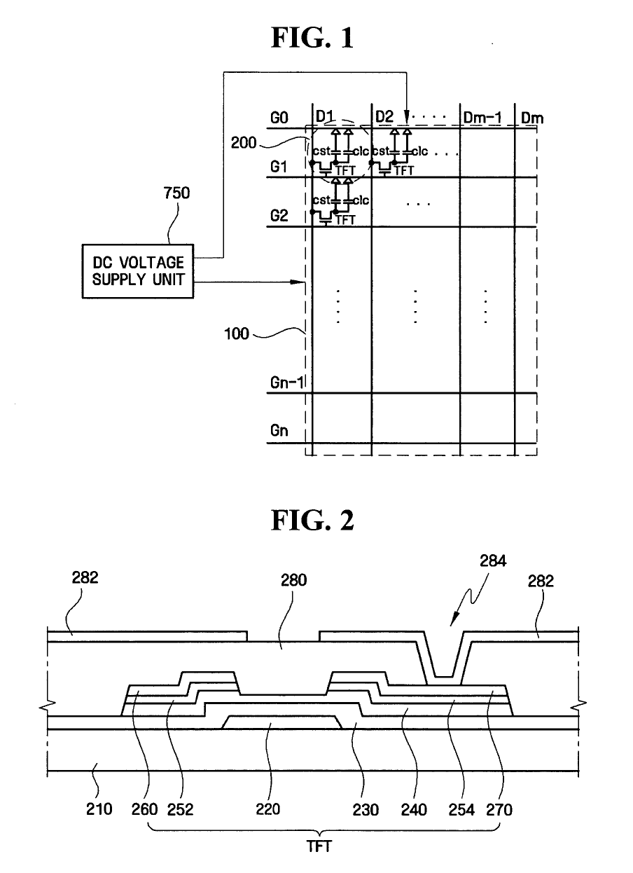

A method of manufacturing a liquid crystal display according to an embodiment of the present invention will be described with reference to FIGS. 1 through 2.

FIG. 1 is a circuit diagram illustrating a connection between a liquid crystal panel in a liquid crystal display according to an embodiment of the present invention and a direct current voltage supply unit, and FIG. 2 is a sectional view of a thin film transistor of a liquid crystal display according to an embodiment of the present invention.

Referring to FIGS. 1 and 2, a liquid crystal panel 100 controls the activation and deactivation operation of a thin film transistor TFT using signals received from gate lines G1, . . . , Gn, and the orientation of liquid crystals using signals received from data lines D1, . . . , Dm. The liquid crystal panel 100 includes the gate lines G1, . . . , Gn, the data lines D1, . . . , Dm, and a plurality of pixels 200.

The gate lines G1, . . . , Gn (or signal scan lines) are responsible for gate signal transmission and extend in a row direction.

The data lines D1, . . . , Dm are responsible for image or data signal transmission and extend in a column direction.

Each pixel 200 includes a thin film transistor TFT connected to corresponding gate and data lines, and a liquid crystal capacitor Clc and a sustain capacitor Cst connected to the thin film transistor TFT.

The thin film transistor TFT will now be described in detail with reference to FIG. 2.

The thin film transistor TFT is a three-terminal device formed on a transparent substrate 210 with high light-transmittance. The thin film transistor TFT is formed at each intersection between the gate lines G1, . . . , Gn and the data lines D1, . . . , Dm. The thin film transistor TFT includes a gate electrode 220, a gate insulating layer 230, a semiconductor layer 240, first and second ohmic contact layers 252 and 254, a drain electrode 260, and a source electrode 270.

The gate electrode 220 is connected to a corresponding gate line and receives a gate-on voltage (Von) or a gate-off voltage (Voff) from the corresponding gate line to control an activation/deactivation operation of the thin film transistor TFT. The gate insulating film 230 made of an inorganic insulating material is formed on the gate electrode 220.

The semiconductor layer 240 defines a channel of the thin film transistor TFT. The semiconductor layer 240 is formed on the gate insulating layer 230 in such a way to cover an exposed portion of the gate insulating layer 230 between the drain electrode 260 and the source electrode 270 and extend over both ends of the gate electrode 220 to form a projection around the gate electrode 220. The semiconductor layer 240 is made of amorphous silicon and thus includes a dangling bond and a weak Si—Si bond. In the liquid crystal display according to the embodiment shown in FIG. 2, the semiconductor layer 240 is implemented as a semiconductor layer formed by a four-mask process. However, the semiconductor layer 240 is not limited, provided that it is formed as a projecting structure around the gate electrode 220.

The first and second ohmic contact layers 252 and 254 serve to reduce a contact resistance between the semiconductor layer 240 and the drain electrode 260 and between the semiconductor layer 240 and the source electrode 270, respectively. The first and second ohmic contact layers 252 and 254 are paired together on the semiconductor layer 240. The first and second ohmic contact layers 252 and 254 are made of silicide or n+ amorphous silicon.

The drain electrode 260 transmits a signal received from a corresponding data line to the thin film transistor TFT. The drain electrode 260 is connected to a corresponding data line and formed on the first ohmic contact layer 252.

The source electrode 270 transmits a signal applied to the drain electrode 260 to a pixel electrode 282. The source electrode 270 is formed on the second ohmic contact layer 254 to be opposite to the drain electrode 260.

Meanwhile, the pixel electrode 282 is connected to the source electrode 270 through a contact hole 284 in an organic insulating layer 280 to receive the signal applied to the drain electrode 260.

The liquid crystal capacitor Clc includes the pixel electrode 282, a common electrode (not shown) formed on a color filter (not shown), and a liquid crystal layer (not shown) interposed therebetween. A common voltage is applied to the common electrode.

The sustain capacitor Cst (not shown) includes the overlying gate line, the pixel electrode 282 and the gate insulating layer 230.

The sustain capacitor Cst can adopt a previous gate type driving method or a common electrode type driving method may also be used.

A direct current (DC) voltage supply unit 750 stabilizes the semiconductor layer 240 made of amorphous silicon to reduce a residual image on a residual image test pattern in a residual image test. The DC voltage supply unit 750 supplies DC voltages to the gate electrode 220 and the drain electrode 260. The DC voltage supply unit 750 supplies a DC voltage of about −25 to −30 V to the gate electrode 220 and a ground voltage to the drain electrode 260.

When a voltage applied to the gate electrode 220 to deactivate the thin film transistor TFT upon normal operation of the liquid crystal panel 100 is V1, a maximal voltage applied to the drain electrode 260 upon normal operation of the liquid crystal panel 100 is V2, a voltage applied to the gate electrode 220 is Vg, and a voltage applied to the drain electrode 260 is Vd, Vg and Vd satisfy the inequality Vg-Vd<V1-V2 within permissible voltage ranges of the gate electrode 220 and the drain electrode 260. Here, the maximal voltage V2 applied to the drain electrode 260 during normal operation of the liquid crystal panel 100 is the same as an array power voltage (AVdd) generated in a driving voltage generating unit (see 510 of FIG. 4) of a liquid crystal display (see 1 of FIG. 4).

A method of manufacturing a liquid crystal display according to an embodiment of the present invention will be described with reference to FIGS. 1 through 3.

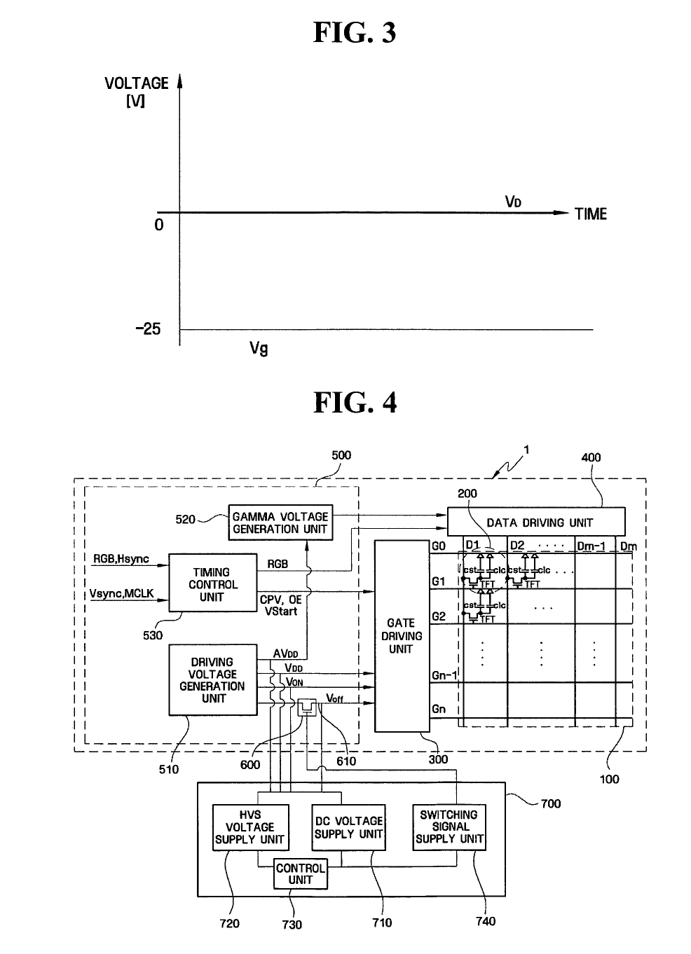

FIG. 3 illustrates applied voltage levels in a method of manufacturing a liquid crystal display according to an embodiment of the present invention.

The DC voltage supply unit 750 is connected to the gate lines G1, . . . , Gn and the data lines D1, . . . , Dm of the liquid crystal panel 100.

As shown in FIG. 3, the DC voltage supply unit 750 generates about −25 V as a DC voltage for the gate electrode 220 and a ground voltage as a DC voltage for the drain electrode 260. The generated voltages are applied to the gate electrode 220 and the drain electrode 260 of each thin film transistor TFT along corresponding gate and data lines.

Thus, a DC voltage of about −25 V is applied to the gate electrode 220, the drain electrode 260 is grounded, and the source electrode 270 is floated.

This embodiment of the present invention illustrates that a voltage of about −25 V is applied to the gate electrode 220 and the drain electrode 260 is grounded. However, the present invention is not limited thereto provided that when a voltage applied to the gate electrode 220 to deactivate the thin film transistor TFT upon normal operation of the liquid crystal panel 100 is V1, a maximal voltage applied to the drain electrode 260 upon normal operation of the liquid crystal panel 100 is V2, a voltage applied to the gate electrode 220 is Vg, and a voltage applied to the drain electrode 260 is Vd, Vg and Vd satisfy the inequality Vg-Vd<V1-V2 within permissible voltage ranges of the gate electrode 220 and the drain electrode 260. Here, the maximal voltage V2 applied to the drain electrode 260 during normal operation of the liquid crystal panel 100 is the same as an array power voltage (AVdd) generated in a driving voltage generating unit (see 510 of FIG. 4) of a liquid crystal display (see 1 of FIG. 4).

Here, the DC voltage supply unit 750 applies a voltage to each electrode for 10 minutes or greater.

FIG. 4 is a circuit diagram illustrating a connection between a liquid crystal display according to an embodiment of the present invention and an aging system according to an embodiment of the present invention.

Referring to FIG. 4, the liquid crystal display 1 includes a liquid crystal panel 100, a gate driving unit 300, a data driving unit 400, and a printed circuit board 500.

Since the liquid crystal panel 100 is the same as described above, a repeated explanation thereof will not be given. In the following description, the gate driving unit 300, the data driving unit 400, and the printed circuit board 500 will now be described in more detail.

The gate driving unit 300, which is also called a scan driving unit, is connected to gate lines G1, . . . , Gn of the liquid crystal panel 100, and applies a gate signal composed of the combination of a gate-on voltage Von and a gate-off voltage Voff from a driving voltage generating unit 510 to the gate lines G1, . . . , Gn. The gate driving unit 300 may be mounted on a gate tape carrier package (not shown).

The data driving unit 400 is connected to data lines D1, . . . , Dm of the liquid crystal panel 100 and applies a data signal to the data lines D1, . . . , Dm. The data driving unit 400 may be mounted on a data tape carrier package.

The printed circuit board 500 is electrically connected to the gate tape carrier package and the data tape carrier package to supply a driving voltage to the gate driving unit 300 or to supply a data signal to the data driving unit 400. The printed circuit board 500 includes the driving voltage generating unit 510, a gamma voltage generating unit 520, a timing control unit 530, and a switching unit 600.

The driving voltage generating unit 510 generates a gate-on voltage Von for activating each thin film transistor TFT, a gate-off voltage Voff for deactivating each thin film transistor TFT, a common voltage Vcom (not shown), an array power voltage AVdd for gamma voltage generation, and a power voltage Vdd.

The gamma voltage generating unit 520 generates a gamma voltage based on the array power voltage AVdd from the driving voltage generating unit 510 and supplies the generated gamma voltage to the data driving unit 400.

The timing control unit 530 generates control signals for controlling the operations of the gate driving unit 300, the data driving unit 400, the driving voltage generating unit 510, etc., and supplies corresponding control signals to the gate driving unit 300, the data driving unit 400, and the driving voltage generating unit 510.

The switching unit 600 determines the transmission of the gate-off voltage Voff from the driving voltage generating unit 510 to the gate driving unit 300, and protects the driving voltage generating unit 510 from a voltage derived from a DC voltage supply unit 710. The switching unit 600 disconnects the driving voltage generating unit 510 and the gate driving unit 300 from each other by a signal generated in a switching signal supply unit 740 of an aging system 700. For example, in a case where the switching unit 600 is an n-type metal oxide semiconductor field-effect transistor, when a voltage less than a predetermined value is applied to a gate electrode (not shown) of the switching unit 600, current does not flow in a channel layer (not shown) of the switching unit 600, thus disconnecting the driving voltage generating unit 510 and the gate driving unit 300 from each other. The switching unit 600 may be formed on a gate-off voltage line 610.

In this embodiment of the present invention, the switching unit 600 is implemented as a semiconductor field-effect transistor. However, the switching unit 600 is not particularly limited provided that it has a switching effect.

The aging system 700 supplies a voltage for stabilizing a semiconductor layer (see 240 of FIG. 2) of each thin film transistor (TFT), the gate driving unit 300, and the data driving unit 400 in the liquid crystal display 1. The aging system 700 includes the DC voltage supply unit 710, a HVS (High Voltage Stress) voltage supply unit 720, a control unit 730, and the switching signal supply unit 740.

The DC voltage supply unit 710 stabilizes a semiconductor layer (see 240 of FIG. 2) made of amorphous silicon of the liquid crystal panel 100 to reduce a residual image from being exhibited on a residual image test pattern in a residual image test. The DC voltage supply unit 710 supplies DC voltages to the gate driving unit 300 and the gamma voltage generating unit 520. The DC voltage supply unit 710 supplies a gate-off voltage Voff, a gate-on voltage Von, and a power voltage Vdd to the gate driving unit 300, and an array power voltage AVdd to the data driving unit 400. The DC voltage supply unit 710 supplies about −25 V to about −30 V as a gate-off voltage Voff, and a ground voltage as the gate-on voltage Von, the power voltage Vdd, and the array power voltage A-Vdd. Here, the gate-off voltage Voff and the array power voltage AVdd are applied to a gate electrode (see 220 of FIG. 2) and a drain electrode (see 260 of FIG. 2), respectively.

This embodiment of the present invention illustrates that the gate-off voltage Voff is in a range of about −25 V to about −30 V and the array power voltage AVdd is a ground voltage. However, the present invention is not limited thereto provided that when a voltage applied to a gate electrode (see 220 of FIG. 2) to deactivate a thin film transistor (TFT) upon normal operation of the liquid panel 100 is V1, a maximal voltage applied to a drain electrode (see 260 of FIG. 2) upon normal operation of the liquid crystal panel 100 is V2, the gate-off voltage Voff is Va, and the array power voltage AVdd is Vb, Va and Vb satisfy the inequality Va-Vb<V1-V2 within permissible voltage ranges of the gate electrode and the drain electrode. Here, the maximal voltage V2 applied to a drain electrode (see 260 of FIG. 2) upon normal operation of the liquid crystal panel 100 is the same as the array power voltage AVdd generated in the driving voltage generating unit 510 of the liquid crystal display 1.

The HVS voltage supply unit 720 supplies voltages for stabilizing the gate driving unit 300 and the data driving unit 400 of the liquid crystal display 1. The HVS voltage supply unit 720 supplies a gate-on voltage Von, a gate-off voltage Voff, and a power voltage Vdd to the gate driving unit 300, and an array power voltage AVdd to the gamma voltage generating unit 520. The HVS voltage supply unit 720 supplies about 33V as the gate-on voltage Von, about −8V as the gate-off voltage Voff, about 3.3V as the power voltage Vdd, and about 13V as the array power voltage AVdd.

The control unit 730 selects voltages to be supplied to the liquid crystal display 1 from the aging system 700, and controls the operation of the switching signal supply unit 740. The control unit 730 transmits an operation start signal to the DC voltage supply unit 710 and the switching signal supply unit.740, and at the same time, stops the operation of the HVS voltage supply unit 720.

The switching signal supply unit 740 receives the operation start signal from the control unit 730 and generates a signal to be supplied to the switching unit 600. The switching signal supply unit 740 is connected to the switching unit 600 on the gate-off voltage line 610.

A method of manufacturing a liquid crystal display according to another embodiment of the present invention will now be described with reference to FIGS. 4, 5 and 6.

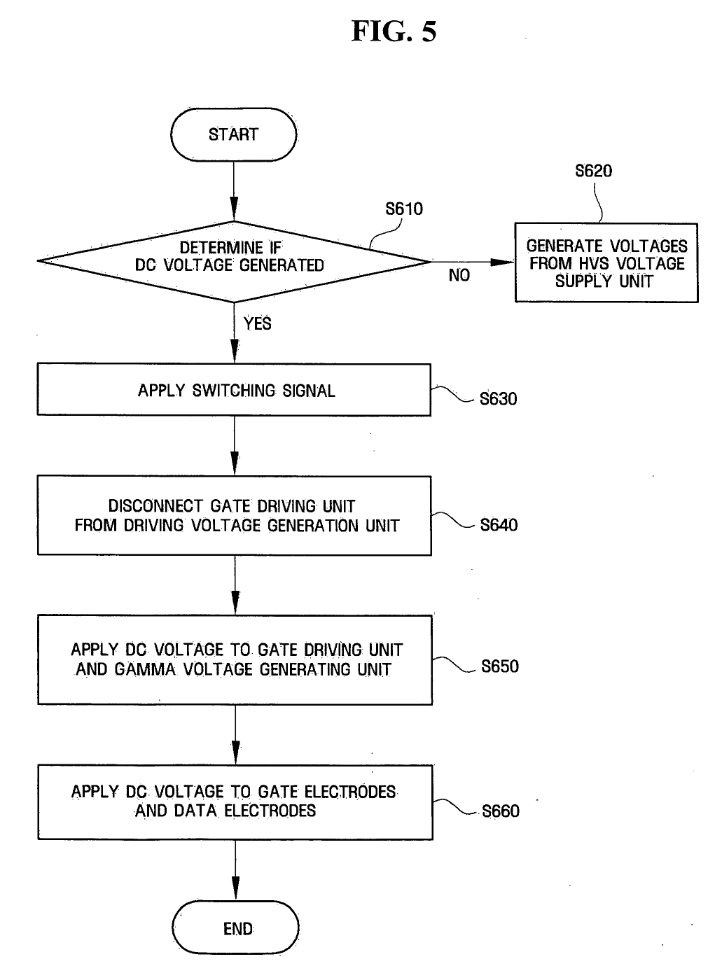

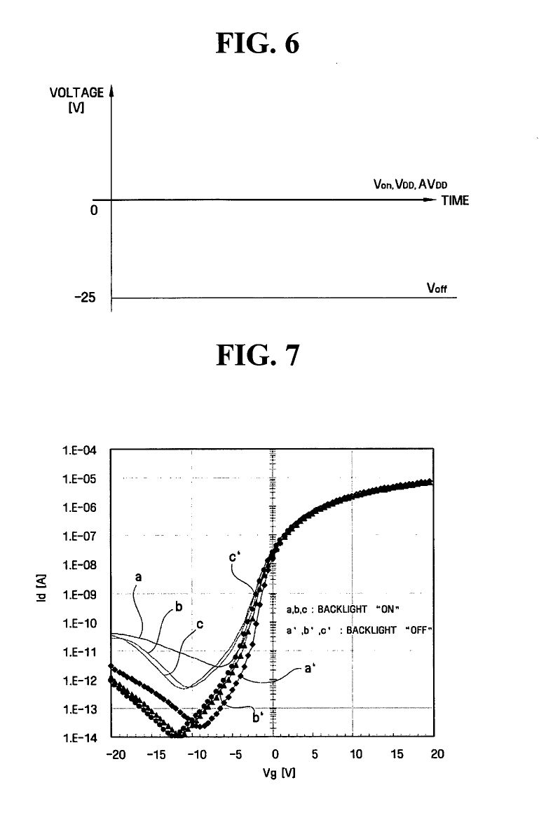

FIG. 5 is a flow diagram illustrating a method of manufacturing a liquid crystal display according to another embodiment of the present invention, and FIG. 6 illustrates voltage levels to be applied from a direct current voltage supply unit in the method of manufacturing a liquid crystal display according to another embodiment of the present invention.

In operation S610, it is determined whether DC voltages are generated in the DC voltage supply unit 710 by an input signal from the control unit 730. If no DC voltages are generated in operation S610, voltages are generated in the HVS voltage supply unit 720 in operation S620.

Referring to FIG. 6, the DC voltage supply unit 710 supplies about −25 V as the gate-off voltage Voff, and a ground voltage as the gate-on voltage Von, the power voltage Vdd, and the array power voltage AVdd. Here, the gate-off voltage Voff and the array power voltage AVdd are applied to a gate electrode (see 220 of FIG. 2) and a drain electrode (see 260 of FIG. 2), respectively.

This embodiment of the present invention illustrates that the gate-off voltage Voff is about −25 V and the array power voltage AVdd is a ground voltage. However, the present invention is not limited thereto provided that when a voltage applied to a gate electrode (see 220 of FIG. 2) to deactivate a thin film transistor (TFT) upon normal operation of the liquid panel 100 is V1, a maximal voltage applied to a drain electrode (see 260 of FIG. 2) upon normal operation of the liquid crystal panel 100 is V2, the gate-off voltage Voff is Va, and the array power voltage AVdd is Vb, Va and Vb satisfy the inequality Va-Vb<V1-V2 within permissible voltage ranges of the gate electrode and the drain electrode. Here, the maximal voltage level V2 applied to the drain electrode (see 260 of FIG. 2) upon normal operation of the liquid crystal panel 100 is the same as the array power voltage AVdd generated in the driving voltage generating unit 510 of the liquid crystal display 1.

Then, a predetermined signal for disconnection of the gate driving unit 300 and the driving voltage generating unit 510 from each other is supplied from the switching signal supply unit 740 to the switching unit 600 in operation S630.

In operation S640, the gate driving unit 300 and the driving voltage generating unit 510 are disconnected from each other by the switching unit 600 to avoid circuit damage to the driving voltage generating unit 510.

The voltages generated in the DC voltage supply unit 710 are applied to the gate driving unit 300 and the gamma voltage generating unit 520 in operation S650. The DC voltage applied to the gate driving unit 300 is applied to gate electrodes (see 220 of FIG. 2) via the gate lines G0, . . . , Gn, and the ground voltage applied to the gamma voltage generating unit 520 is applied to drain electrodes (see 260 of FIG. 260) via the data driving unit 400 and the data lines D1, . . . , Dm (operation S660). At this time, source electrodes (see 270 of FIG. 2) are floated. The voltage application of the DC voltage supply unit 710 is continued for 10 minutes or greater.

A voltage applied to a gate electrode (see 220 of FIG. 2) of a thin film transistor is lower than a ground voltage applied to a drain electrode (see 260 of FIG. 2), and thus a Fermi level is shifted to a valence band. A voltage applied to a semiconductor layer (see 240 of FIG. 2) of a thin film transistor is lower than that applied to the drain electrode, and thus the semiconductor layer includes more dangling bonds than weak Si—Si bonds.

The present invention will be described in detail through the following experimental examples. However, the experimental examples are for illustrative purposes and other examples and applications can be readily envisioned by a person of ordinary skill in the art. Since a person skilled in the art can sufficiently analogize the technical content which is not described in the following experimental examples, the description thereof is omitted.

### EXPERIMENTAL EXAMPLE 1

Leakage current was measured for liquid crystal displays when a backlight was activated, as indicated by plots a, b, and c of FIG. 7, and when a backlight was deactivated, as indicated by plots a′, b′, and c′ of FIG. 7. The result of the leakage current levels measured is illustrated in FIG. 7.

FIG. 7 graphically represents a change in the light leakage current when an application of a method of manufacturing a liquid crystal display according to an embodiment of the present invention is not made, when the application of the method is made and an application of white-stress after the application of the method, in which the x-axis indicates a voltage applied to a gate electrode and the y-axis indicates leakage current.

In FIG. 7, the plots a and a′ show leakage current measurements when a voltage ranging from about −20 V to about 20 V at about 0.5 V intervals is applied to a gate electrode, about 10 V is applied to a drain electrode, and a ground voltage is applied to a source electrode.

The plots b and b′ show leakage current measurements when about −30 V is applied to a gate electrode for approximately 10 minutes, a drain electrode is grounded, and a source electrode is floated, according to a method of manufacturing a liquid crystal display of an embodiment of the present invention.

The plots c and c′ show leakage current measurements after white-stress is applied to liquid crystal displays manufactured according to a method of manufacturing a liquid crystal display of an embodiment of the present invention. The white-stress is a simulated stress for the voltage state of a white driving region. To this end, about −7V, 6V, and 12V were applied to a gate electrode, a drain electrode, and a source electrode, respectively, for approximately 10 minutes.

Comparing the plots a′ and c′, a maximal leakage current difference was about 9×10⁻¹⁴A. However, comparing the plots b′ and c′, little difference in the leakage current occurred.

Comparing the plots a and c, a maximal leakage current difference was about 9×10⁻¹³A. However, comparing the plots b and c, little difference in the leakage current occurred.

Here, when a thin film transistor was deactivated in an active state of a backlight, a leakage current difference between the plots a and c was the greatest. This is because a change in leakage current occurs in a thin film transistor before and after white-stress application in an active state of a backlight. Such a leakage current change induces a difference in voltage applied to a sustain capacitor, leaving a residual image on a residual image test pattern during a residual image test. However, since a leakage current difference between the plots b and c is insignificant, no difference in voltage applied to a sustain capacitor is created. Therefore, no residual image is formed on a residual image test pattern during a residual image test, exhibiting a residual image enhancement effect.

A semiconductor layer made of amorphous silicon locally includes a weak Si—Si bond and a dangling bond due to a random atomic arrangement. According to a method of manufacturing a liquid crystal display of an embodiment of the present invention, a dangling bond density increases and a weak Si—Si bond density decreases by an electric field applied to a semiconductor layer made of amorphous silicon, and thus, the semiconductor layer is stabilized, thereby leading to residual image enhancement. That is, a Fermi level of the semiconductor layer made of amorphous silicon is lowered, which changes the characteristics of a thin film transistor.

### EXPERIMENTAL EXAMPLE 2

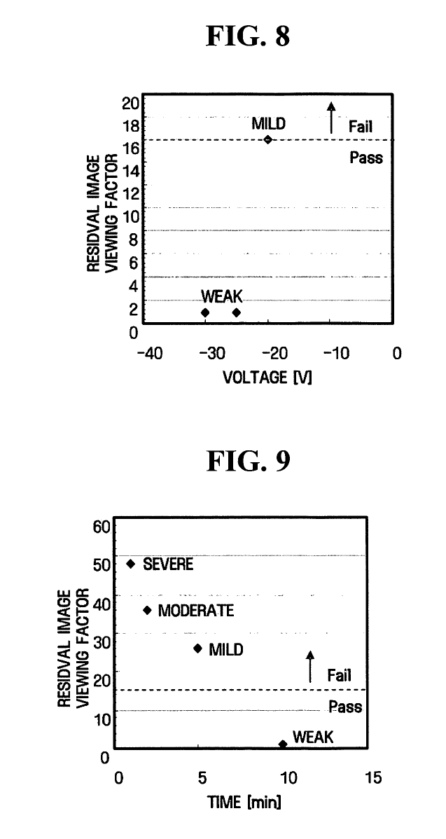

A residual image viewing factor with respect to a voltage applied to a gate electrode was evaluated in performing a method of manufacturing a liquid crystal display according to an embodiment of the present invention. At this time, a voltage from about −20 V to about −30 V at about 5 V intervals was applied to a gate electrode for approximately 10 minutes, a drain electrode was grounded, and a source electrode was floated. A residual image viewing factor was evaluated by visually observing a residual image on a residual image test pattern using test gradation ranging from 1 to 64. A residual image viewing factor was defined based on gradations at which a weak residual image was observed. The results are shown in FIG. 8.

FIG. 8 graphically represents a residual image viewing factor with respect to a voltage applied to a gate electrode in a method of manufacturing a liquid crystal display according to an embodiment of the present invention, in which the x-axis indicates a voltage applied to a gate electrode and the y-axis indicates a residual image viewing factor. A residual image viewing factor was reduced to less than 1 when about −25 V or less was applied to a gate electrode, which shows residual image enhancement.

### EXPERIMENTAL EXAMPLE 3

A residual image viewing factor with respect to a voltage application time was evaluated in performing a method of manufacturing a liquid crystal display according to an embodiment of the present invention. Here, about −25 V was applied to a gate electrode, a drain electrode was grounded, and a source electrode was floated. The results are shown in FIG. 9.

FIG. 9 graphically represents a residual image viewing factor with respect to a voltage application time in a method of manufacturing a liquid crystal display according to an embodiment of the present invention.

In FIG. 9, the x-axis indicates a time for voltage application to a gate electrode and the y-axis indicates a residual image viewing factor. Referring to FIG. 9, a residual image viewing factor was reduced to less than 1 as the time for voltage application to the gate electrode exceeded 10 minutes, which shows residual image enhancement.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A method of manufacturing a liquid crystal display, the method comprising:
providing a liquid crystal display including a liquid crystal panel having a plurality of thin film transistors, each thin film transistor comprising a gate electrode, a semiconductor layer formed on the gate electrode, and a drain electrode and a source electrode formed on the semiconductor layer and overlapping respective sides of the gate electrode; and
applying a first voltage to the gate electrode and a second voltage to the drain electrode, wherein the first voltage minus the second voltage is less than a third voltage minus a fourth voltage, in which the third voltage is a voltage applied to the gate electrode to deactivate the plurality of thin film transistors upon normal operation of the liquid crystal panel, and the fourth voltage is a maximal voltage applied to the drain electrode upon normal operation of the liquid crystal panel.

2. The method of claim 1, wherein the first voltage ranges from about −25 volts to about −30 volts, and the second voltage is a ground voltage.

3. The method of claim 2, wherein when the first voltage is about −25 volts, a voltage application time is about ten (10) minutes or greater.

4. The method of claim 1, wherein the semiconductor layer is formed together with the drain electrode and the source electrode, using a single photoresist film pattern.

5. The method of claim 1, wherein the semiconductor layer is made of amorphous silicon.

6. A method of manufacturing a liquid crystal display, the method comprising:
providing a liquid crystal display including a liquid crystal panel, a driving voltage generating unit, a gate driving unit and a switching unit, the liquid crystal panel having a plurality of thin film transistors, each thin film transistors comprising a gate electrode, a semiconductor layer formed on the gate electrode, and a drain electrode and a source electrode formed on the semiconductor layer and overlapping respective sides of the gate electrode, the driving voltage generating unit supplying a gate-off voltage for deactivating the plurality of thin film transistors, the gate driving unit sequentially applying gate signals to gate lines of the liquid crystal panel, and the switching unit determining the transmission of the gate-off voltage from the driving voltage generating unit to the gate driving unit; and
applying a first voltage to the gate electrode and a second voltage to the drain electrode, wherein the first voltage minus the second voltage is less than a third voltage minus a fourth voltage, in which the third voltage is a voltage applied to the gate electrode to deactivate the plurality of thin film transistors upon normal operation of the liquid crystal panel, and the fourth voltage is a maximal voltage applied to the drain electrode upon normal operation of the liquid crystal panel.

7. The method of claim 6, wherein the switching unit is formed on a gate-off voltage line transmitting the gate-off voltage from the driving voltage generating unit to the gate driving unit.

8. The method of claim 6, wherein the switching unit disconnects the driving voltage generating unit and the gate driving unit from each other when an external voltage is applied to the gate driving unit.

9. The method of claim 6, wherein the first voltage ranges from about −25 volts to about −30 volts, and the second voltage is a ground voltage.

10. The method of claim 9, wherein when the first voltage is about −25 volts, a voltage application time is ten (10) minutes or greater.

11. The method of claim 6, wherein the semiconductor layer is formed together with the drain electrode and the source electrode using a single photoresist film pattern.

12. The method of claim 6, wherein the semiconductor layer is made of amorphous silicon.

13. A liquid crystal display comprising:
a liquid crystal panel having a plurality of thin film transistors, each thin film transistors comprising a gate electrode, a semiconductor layer disposed on the gate electrode, and a drain electrode and a source electrode disposed on the semiconductor layer and overlapping respective sides of the gate electrode;
a driving voltage generating unit supplying a gate-off voltage for deactivating the plurality of thin film transistors;
a gate driving unit sequentially applying gate signals to gate lines of the liquid crystal panel; and
a switching unit determining the transmission of the gate-off voltage from the driving voltage generating unit to the gate driving unit.

14. The liquid crystal display of claim 13, wherein the switching unit is formed on a gate-off voltage line transmitting the gate-off voltage from the driving voltage generating unit to the gate driving unit.

15. The liquid crystal display of claim 13, wherein the switching unit disconnects the driving voltage generating unit and the gate driving unit from each other when an external voltage is applied to the gate driving unit.

16. The liquid crystal display of claim 13, wherein a first voltage is applied to the gate electrode, a second voltage is applied to the drain electrode, and the first voltage minus the second voltage is less than a third voltage minus a fourth voltage, in which the third voltage is a voltage applied to the gate electrode to deactivate the plurality of thin film transistors upon normal operation of the liquid crystal panel, and the fourth voltage is a maximal voltage applied to the drain electrode upon normal operation of the liquid crystal panel.

17. The liquid crystal display of claim 16, wherein the first voltage ranges from about −25 volts to about −30 volts, and the second voltage is a ground voltage.

18. The liquid crystal display of claim 17, wherein when the first voltage is about −25 volts, a voltage application time is ten (10) minutes or greater.

19. The liquid crystal display of claim 13, wherein the semiconductor layer is formed together with the drain electrode and the source electrode, using a single photoresist film pattern.

20. The liquid crystal display of claim 13, wherein the semiconductor layer is made of amorphous silicon.

21. An aging system comprising:
a direct current voltage supply unit applying a first voltage to a gate electrode of a thin film transistor and a second voltage to a drain electrode of the thin film transistor, wherein the first voltage minus the second voltage is less than a third voltage minus a fourth voltage, when the third voltage is a voltage applied to the gate electrode to deactivate the thin film transistor upon normal operation of a liquid crystal display, and the fourth voltage is a maximal voltage applied to the drain electrode upon normal operation of the liquid crystal display; and
a high voltage stress (HVS) voltage supply unit supplying a voltage for stabilizing the gate driving unit and the data driving unit of the liquid crystal display to the gate driving unit and the gamma voltage generating unit, wherein the liquid crystal display includes a driving voltage generating unit supplying a gate-off voltage for deactivating the thin film transistor, a gate driving unit sequentially applying gate signals to gate lines of a liquid crystal panel, a data driving unit applying data signals to data lines of the liquid crystal panel, and a gamma voltage generating unit generating a gamma voltage based on an array power voltage supplied from the driving voltage generating unit.

22. The aging system of claim 21, wherein the direct current voltage supply unit supplies the first voltage ranging from about −25 volts to about −30 volts, and the second voltage of a ground voltage.

23. The aging system of claim 21, wherein the direct current voltage supply unit supplies a gate-off voltage ranging from about −25 volts to about −30 volts to the gate driving unit.

24. The aging system of claim 23 wherein the direct current voltage supply unit supplies a ground voltage as an array power voltage to the gamma voltage generating unit and as a power voltage and a gate-on voltage to the gate driving unit.

25. The aging system of claim 21, further comprising:
a switching unit determining the transmission of the gate-off voltage from the driving voltage generating unit to the gate driving unit; and
a switching signal supply unit supplying a switching signal for deactivating the switching unit when the direct current voltage supply unit applies the gate-off voltage ranging from about −25 volts to about −30 volts to the gate driving unit.
